(19) United States
(12) Patent Application Publication
(10) Pub. No.: US 2006/0245603 A1
(43) Pub. Date: Nov. 2, 2006

(54) Volume controller

(75) Inventors: Nobuyuki Suzuki, Sagamihara-shi (JP); Nobuo Fujiwara, Yokohama-shi (JP)

Correspondence Address: NDQ&M WATCHSTONE LLP, 1300 EYE STREET, NW, 400 EAST TOWER, WASHINGTON, DC, 20005, US

(73) Assignee: KYODO DENSHI ENGINEERING CO., LTD., Yokohama-shi (JP)

(21) Appl. No.: 11/386,753

(22) Filed: Mar. 23, 2006

(30) Foreign Application Priority Data
Mar. 23, 2005 (JP) 2005-084807

(51) Int. Cl. H03G 3/00

(52) U.S. Cl. 381/104

(57) ABSTRACT

An audio signal is input to a step-down transformer 11, where it is attenuated by voltage step-down, and then input via a select switch 12 to a variable resistor 13, where it is further attenuated by voltage division.

### BACKGROUND OF THE INVENTION

1. Field of the Invention

The present invention relates to a volume controller, and in particular, to a volume controller to be used for amplification control of audio signals.

2. Description of Relevant Art

The audio equipment is provided with a preamplifier which inputs audio signals within 2 Hz to 100 KHz (typically, 20 Hz to 20 KHz) from a source equipment (such as a broadcast oriented recording medium, tape and CD with a super-audio inclusive, for example) and performs their preamplification, a power amplifier (or main amplifier) which performs power amplification of preamplified audio signals, and an electroacoustic equipment (such as a speaker) which is driven by power-amplified audio signals, and typically, the preamplifier doubles as a volume controller for amplification control, while a volume controller may be inserted next the preamplifier.

Such a volume controller has conventionally been made up by using a variable resistor, to thereby adjust the attenuance of audio signal.

FIG. 25 shows a conventional volume controller VC20 for audio equipment.

The volume controller VC20 is configured with an input terminal Ti having an audio signal input from a source equipment SA or preamplifier PA, a variable resistor 1 as a potentiometer for dividing a potential of the input terminal Ti relative to a ground line G, i.e., an input voltage e_{IN}, and an output terminal To for outputting a potential of a sliding element 1a of the variable resistor 1 relative to the ground line G as an output voltage eₒ to a main amplifier MA in the next stage. The input voltage e_{IN} is divided by voltage dividing resistances R1 and R2 of the variable resistor 1, this divided voltage e_{IN}·R2/(R1+R2) being the output voltage eo, and hence the audio signal is attenuated by that fraction, achieving a commensurate volume control.

The output terminal To is connected to a control terminal of an amplifying element constituting the main amplifier MA, such as a grid g of a triode valve TR in FIG. 27, having superimposed stray input capacitances thereof, for example, a capacitance Cpg between a plate p and the grid g, and a capacitance Cgk between the grid g and a cathode k of the valve TR. These capacitances Cpg and Cgk are cooperative with an output impedance Zo of the variable resistor 1 to constitute a low-pass filter, causing an attenuation effect in a high frequency range. In particular, the capacitance Cpg, which is multiplied by a voltage gain of the amplifying element due to a Miller effect, has a great influence.

Letting A be the voltage gain, and assuming an equivalent input capacitance Ci such that Ci=Cgk+(A+1)Cpg, it is supposed that the low-pass filter has such a cut-off frequency fc that fc=1/(2πZoCi). This means that the upper cut-off frequency gets lowest when the attenuance ATT=6 dB.

FIG. 27 shows a relationship between the attenuance ATT and the output impedance Zo of the volume controller VC20, and FIG. 28 shows a relationship between the attenuance ATT and the cut-off frequency fc of the high frequency attenuating filter due to the stray capacitance Ci of the volume controller VC20.

For the voltage dividing resistances R1 and R2 of the variable resistor 1, the sum is constant, and the product is inverse proportional. Thus, under such a state that R1=R2, that is, when the attenuance ATT is ½ (=−6 dB), the output impedance Zo has a maximum, while this impedance Zo is lowered, as the attenuance ATT goes away from ½ (=−6 dB), until Zo has a minimum (0Ω), when it bears a maximum volume or a minimum volume.

The output impedance Zo is low in an attenuance range near the maximum volume or the minimum volume. However, in a vicinity of ½ attenuation, the output impedance Zo gets high, rendering low the cut-off frequency fc of the high frequency attenuating filter, which is composed of a parallel combined resistance of the voltage dividing resistances R1 and R2 and stray capacitances between an output side of the volume controller VC20 and an input side of the amplifying element of the main amplifier MA, where audio signals pass, having degraded audio qualities.

To this point, a volume controller that employs a step-down transformer instead of a variable resistor is shown in Japanese Patent Application Laid-Open Publication No. 10-327036.

FIG. 26 shows a conventional volume controller VC21 employing a step-down transformer 61. Like elements to FIG. 25 are designated by like reference characters.

This volume controller VC21 has the step-down transformer 2 connected to an input terminal Ti and provided with n intermediate taps 2-1 to 2-n, and uses a select switch 3 having n selective contacts 3-1 to 3-n one-to-one connected to those taps, allowing an appropriate intermediate tap 2-i (i<i<n) to be selected, to thereby obtain a signal attenuated in correspondence to a position of the tap 2-i, which signal is output from an output terminal To.

The attenuation of signal by the step-down transformer 2 is based on a magnetic coupling, and therefore, the volume controller VC21 is free of audio quality degradation in a vicinity of ½ attenuation.

### SUMMARY OF THE INVENTION

The volume controller VC21 needs the number of intermediate taps 2-1 to 2-n to meet a maximum attenuation width and a desirable resolution, and a number of selective contacts 3-1 to 3-n corresponding thereto, having a commensurately complicated configuration. For example, for an attenuation width of 60 dB to be secured by a resolution of 2 dB, as many as respectively 30 intermediate taps and switch contacts are necessary.

The present invention has been made in view of the foregoing points, and therefore its object is to provide a volume controller that can suppress audio quality degradation in an attenuation range near ½ by a simple configuration.

To achieve the object, according to an aspect of the invention, a volume controller comprises a transformer having an audio signal input from a signal source, a signal acquirer configured to select an intermediate tap of the transformer, to thereby acquire an audio signal corresponding thereto, and a resistance attenuator configured to attenuate an audio signal input from the signal acquirer.

Preferably, the transformer comprises a step-down transformer configured to attenuate the audio signal input from the signal source, the step-down transformer having a plurality of intermediate taps different of attenuance, and the signal acquirer performs a selection of the intermediate tap among the plurality of intermediate taps.

Preferably, the transformer has a winding to have the audio signal input from the signal source, the winding being provided with the intermediate tap.

Preferably, the transformer has a primary winding to have the audio signal input from the signal source, and a secondary winding provided with the intermediate tap.

Preferably, the signal acquirer comprises an intermediate tap selector configured to perform the selection of the intermediate tap by switching the plurality of intermediate taps, and a signal outputter configured to output an audio signal to be input to the resistance attenuator.

Preferably, the intermediate tap selector has a plurality of select switches configured to select different intermediate taps among the plurality of intermediate taps, and the signal outputter is configured to input to the resistance attenuator an audio signal made of a difference between audio signals acquired by the plurality of select switches.

Preferably, the signal outputter comprises an amplifier configured to amplify a signal to be input to the resistance attenuator.

Preferably, the resistance attenuator comprises a continuous variable resistor connected to the signal acquirer.

Preferably, the signal acquirer comprises a first select switch having switch contacts connected to the plurality of intermediate taps, respectively, the resistance attenuator comprises the continuous variable resistor connected to an output end of the first select switch, and a second select switch having a plurality of switch contacts connected to the output end of the first select switch, and a switch contact connected to a slider of the continuous variable resistor, and the second select switch is interlocked with the first select switch.

Preferably, the signal acquirer comprises a first plurality of switch contacts connected to the plurality of intermediate taps, and the resistance attenuator comprises a plurality of serial fixed resistors connected to one of the first plurality of switch contacts, a second plurality of switch contacts connected to nodes between the plurality of fixed resistors, and a select switch adapted for selection of the first plurality of switch contacts and the second plurality of switch contacts.

Preferably, one of the first plurality of switch contacts connected to the plurality of serial fixed resistors is connected to an intermediate tap having a maximal attenuance among the plurality of intermediate taps.

To achieve the object, a volume controller according to a twelfth aspect of the invention comprises a volume controller according to the second aspect, wherein the signal acquirer comprises a first plurality of switch contacts connected to the plurality of intermediate taps, and wherein the resistance attenuator comprises a first select switch connected to one of the first plurality of switch contacts, a second plurality of switch contacts selective by the first select switch, a plurality of fixed voltage dividing circuits connected to the second plurality of switch contacts, respectively, a third plurality of switch contacts connected to output ends of the plurality of fixed voltage dividing circuits, and a second select switch adapted for selection of the first plurality of switch contacts and the third plurality of switch contacts.

To achieve the object, according to another aspect of the invention, a volume controller comprises a step-down transformer configured to attenuate an input audio signal, and provided with a plurality of intermediate taps to output the audio signal depending on respective attenuances, a select switch configured to select one of the plurality of intermediate taps in accordance with a manipulation, and a variable resistor connected to an output side of the select switch, and adapted for the audio signal to be continuously attenuated to be output by a change of resistance value in accordance with a manipulation.

To achieve the object, according to another aspect of the invention, a volume controller comprises a step-down transformer configured to attenuate an input audio signal, and provided with a plurality of intermediate taps to output the audio signal depending on respective attenuances, a select switch configured to select one of the plurality of intermediate taps in accordance with a manipulation, an amplifier connected to an output side of the select switch and configured to amplify the audio signal, and a variable resistor connected to an output side of the amplifier, and adapted for the audio signal to be continuously attenuated to be output by a change of resistance value in accordance with a manipulation.

To achieve the object, according to another aspect of the invention, a volume controller comprises a step-down transformer configured to attenuate an input audio signal, and provided with a plurality of intermediate taps to output the audio signal depending on respective attenuances, a first select switch configured to select one of the plurality of intermediate taps in accordance with a manipulation, a second select switch configured to select one of the plurality of intermediate taps in accordance with a manipulation, and a variable resistor having an input end connected to an output side of the first select switch and another input end connected to an output side of the second select switch, and adapted for the audio signal to be continuously attenuated to be output by a change of resistance value in accordance with a manipulation.

To achieve the object, according to another aspect of the invention, a volume controller comprises a step-down transformer configured to attenuate an input audio signal, and provided with a plurality of intermediate taps to output the audio signal depending on respective attenuances, a first select switch configured to select one of the plurality of intermediate taps in accordance with a manipulation, a variable resistor connected to an output side of the first select switch, and adapted for the audio signal to be continuously attenuated to be output by a change of resistance value in accordance with a manipulation, and a second select switch connected to output sides of the variable resistor and the first select switch, and configured to operate in an interlocked manner with the first select switch in accordance with a manipulation, the second select switch being adapted to output an output signal of the variable resistor simply when the first select switch selects an intermediate tap at which the audio signal has a maximized attenuance, and output an output signal of the first select switch when the first select switch selects another intermediate tap.

To achieve the object, according to another aspect of the invention, a volume controller comprises a step-down transformer configured to attenuate an input audio signal, and provided with a plurality of intermediate taps to output the audio signal depending on respective attenuances, a first select switch configured to select one of the plurality of intermediate taps in accordance with a manipulation, an amplifier connected to an output side of the first select switch, and configured to amplify the audio signal, a variable resistor connected to an output side of the amplifier, and adapted for the audio signal to be continuously attenuated to be output by a change of resistance value in accordance with a manipulation, and a second select switch connected to output sides of the variable resistor and the first select switch, and configured to operate in an interlocked manner with the first select switch in accordance with a manipulation, the second select switch being adapted to output an output signal of the variable resistor simply when the first select switch selects an intermediate tap at which the audio signal has a maximized attenuance, and output an output signal of the first select switch when the first select switch selects another intermediate tap.

To achieve the object, according to another aspect of the invention, a volume controller comprises a step-down transformer configured to attenuate an input audio signal, and provided with a plurality of intermediate taps to output the audio signal depending on respective attenuances, a switching type resistor having an input terminal connected to an intermediate tap at which the audio signal has a maximized attenuance, and a plurality of output terminals adapted for the audio signal input from the intermediate tap to be stepwise attenuated to be output, and a select switch configured to select one of the plurality of intermediate taps and the plurality of output terminals of the switching type resistor in accordance with a manipulation.

Preferably, the step-down transformer is a step-down transformer having a primary and secondary independent winding structure.

### BRIEF DESCRIPTION OF THE ACCOMPANYING DRAWINGS

The above and further objects, features, and advantages of the present invention will more fully appear from the detailed description of the preferred embodiments, when the same is read in conjunction with the accompanying drawings, in which:

FIG. 1 is a circuit diagram of a volume controller according to a first embodiment of the present invention;

FIG. 2 is an output level diagram of the volume controller of FIG. 1;

FIG. 3 is a photograph of an essential portion of the volume controller of FIG. 1;

FIG. 4 is a characteristic diagram of a step-down transformer of the volume controller of FIG. 1;

FIG. 5 is a characteristic diagram of the step-down transformer of the volume controller of FIG. 1;

FIG. 6 is a characteristic diagram of the step-down transformer of the volume controller of FIG. 1;

FIG. 7 is a circuit diagram of a volume controller according to a second embodiment of the present invention;

FIG. 8 is a circuit diagram of a volume controller according to a third embodiment of the present invention;

FIG. 9 is an output level diagram of the volume controller of FIG. 8;

FIG. 10 is a circuit diagram of a volume controller according to a fourth embodiment of the present invention;

FIG. 11 is an output level diagram of the volume controller of FIG. 10;

FIG. 12 is a user interface of the volume controller of FIG. 10;

FIG. 13 is a circuit diagram of a volume controller according to a fifth embodiment of the present invention;

FIG. 14 is a circuit diagram of a volume controller according to a sixth embodiment of the present invention;

FIG. 15 is a user interface of the volume controller of FIG. 14;

FIG. 16 is a circuit diagram of a volume controller according to a seventh embodiment of the present invention;

FIG. 17 is a circuit diagram of a volume controller according to an eighth embodiment of the present invention;

FIG. 18 is a photograph of the volume controller of FIG. 17;

FIG. 19 is a perspective view from a rear side of an audio system including a volume controller according to a ninth embodiment of the present invention;

FIG. 20 is a perspective view from a front side of the audio system of FIG. 19;

FIG. 21 is a block diagram of a volume controller according to a tenth embodiment of the present invention;

FIG. 22 is a front view of the volume controller of FIG. 21;

FIG. 23 is a block diagram of a volume controller according to an eleventh embodiment of the present invention;

FIG. 24 is a front view of the volume controller of FIG. 23;

FIG. 25 is a circuit diagram of a conventional volume controller of an audio equipment;

FIG. 26 is a circuit diagram of a conventional volume controller employing a step-down transformer;

FIG. 27 is a graph of a relationship between attenuance and output impedance of the volume controller of FIG. 25;

FIG. 28 is a graph of a relationship between attenuance and upper cut-off frequency of a high frequency attenuating filter due to stray capacitances of the volume controller of FIG. 25; and

FIG. 29 is a circuit diagram of a volume controlling circuit of the volume controller of FIG. 17.

### DETAILED DESCRIPTION OF THE PREFERRED EMBODIMENTS

There will be described preferred embodiments of the present invention into details, with reference to the accompanying drawings. In the drawings, like elements are designated by like reference characters.

### First Embodiment

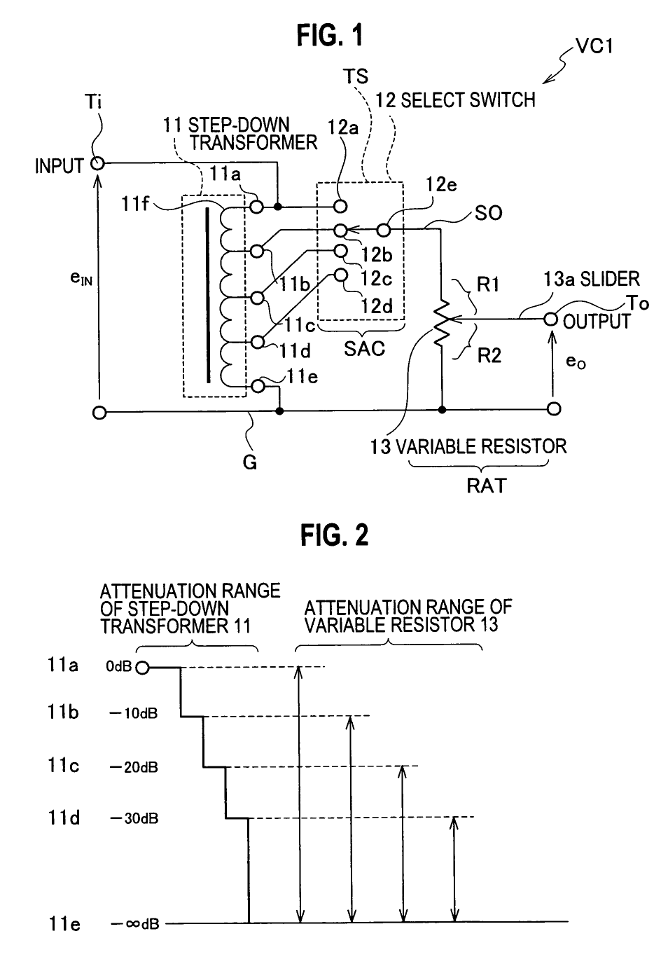

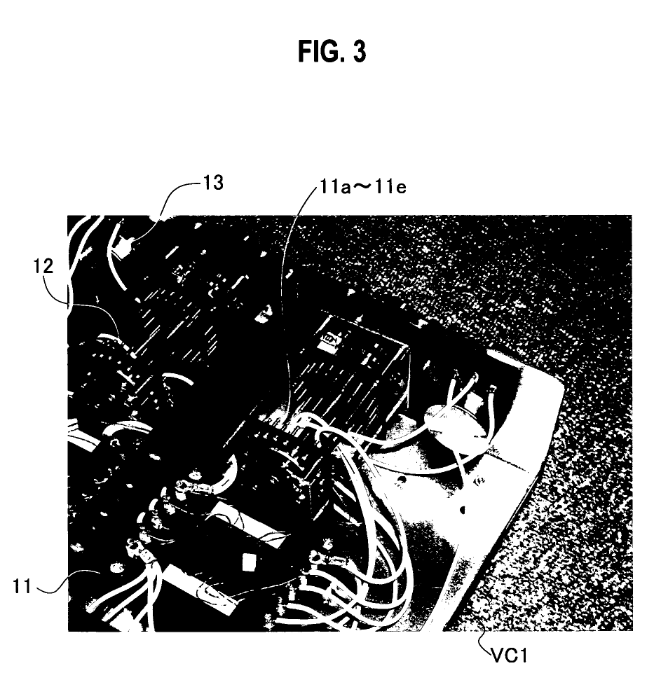

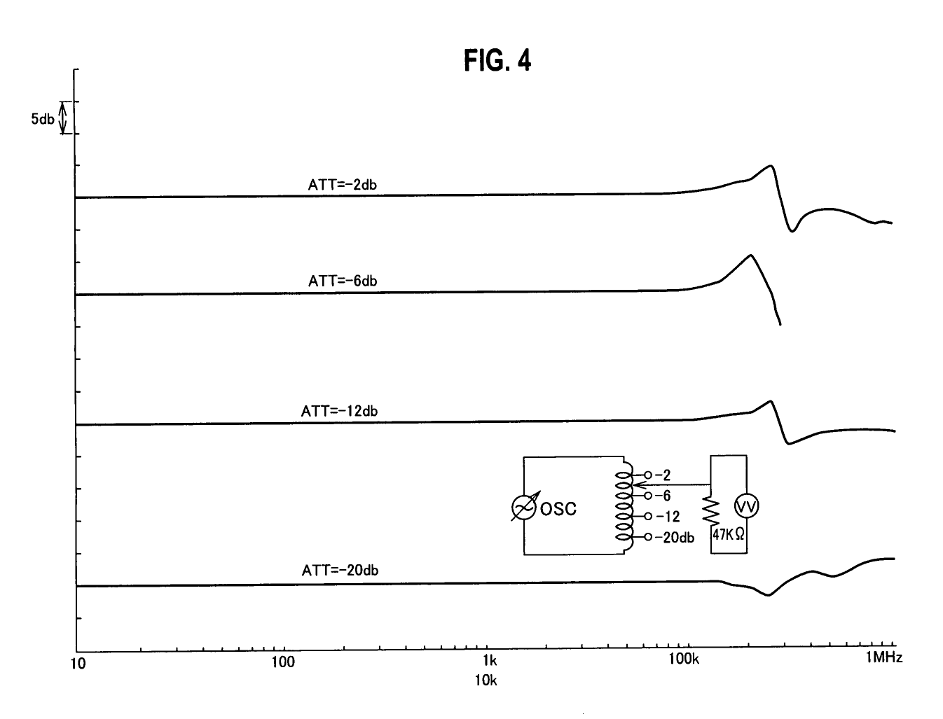

Description is first made of a volume controller VC1 according to a first embodiment of the present invention, with reference to FIG. 1 to FIG. 6. FIG. 1 is a circuit diagram of the volume controller VC1, FIG. 2, an output level diagram of the volume controller VC1, FIG. 3, a photograph of an essential portion of the volume controller VC1, and FIG. 4 to FIG. 6, characteristic diagrams of a step-down transformer 11 of the volume controller VC1.

The volume controller VC1 is configured with: the step-down transformer 11 configured for a voltage step-down to attenuate an audio signal input from an unshown signal source (source equipment or preamplifier); a signal acquirer SAC configured to select one of a plurality of (five in this embodiment) intermediate taps 11a, 11b, 11c, 11d, and 11e different of attenuance of the transformer 11 to thereby acquire a corresponding audio signal; and a resistance attenuator RAT configured to attenuate an audio signal input from the signal acquirer SAC.

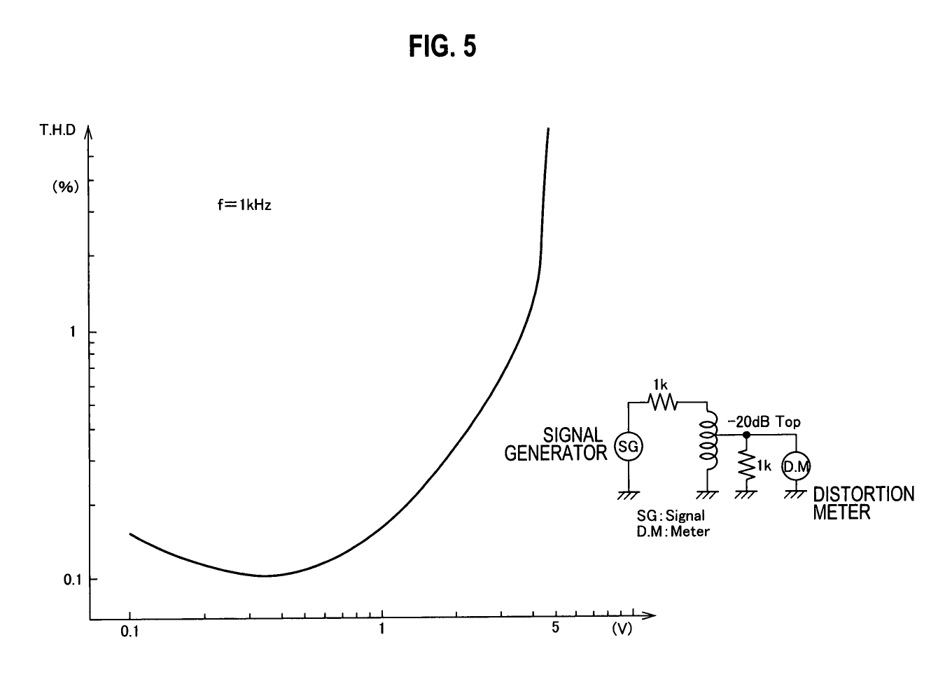

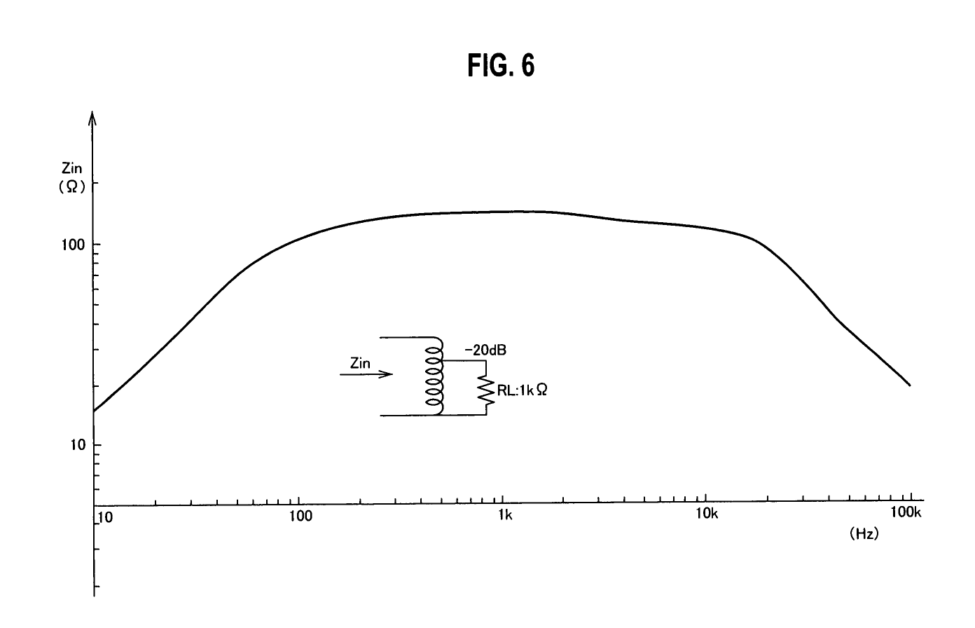

The step-down transformer 11 has a winding 11f to have the audio signal input from the signal source, and the intermediate taps 11a to 11e are provided on the winding 11f. This step-down transformer has an ATT (attenuance) vs. f (frequency) characteristic shown in FIG. 4, a THD (total harmonic distortion) vs. e_{IN} (input voltage) characteristic shown in FIG. 5, and a Zin (input impedance) vs. f (frequency) characteristic shown in FIG. 6.

The signal acquirer SAC is configured with: a select switch 12 as an intermediate tap selector TS for performing an intermediate tap selection by switching the intermediate taps 11a to 11d; and a signal outputter SO for outputting an audio signal to be input to the resistance attenuator RAT from the select switch 12.

The resistance attenuator RAT is configured with a continuous variable resistor 13 connected to the signal acquirer SAC.

Namely, as shown in FIG. 1, the volume controller VC1 is configured with: the step-down transformer 11 having the plurality of intermediate taps 11a to 11e for stepping down the input audio signal; the select switch 12 having switch terminals 12a to 12d for selecting one of the intermediate taps 11a to 11d; and the variable resistor 13 connected to an output terminal 12e of the select switch 12, and adapted for the audio signal to be continuously attenuated to be output.

The intermediate taps 11a to 11d have different attenuances, respectively, and are connected to the switch terminals 12a to 12d of the select switch 12. The variable resistor 13 has a slider 13a, and performs a voltage division by a resistance R1 between the slider 13a and the output terminal 12e, and a resistance R2 of the rest.

When an audio signal is input to the volume controller VC1, the voltage is stepped down by the step-down transformer 11. The stepped down audio signal is output from an intermediate tap to the variable resistor 13 via the select switch 12. In case the terminals 12b and 12e of the select switch 12 are interconnected, for example, the signal is output from the intermediate tap 11b to the variable resistor 13 via the terminals 12b and 12e.

The signal input to the variable resistor 13 is voltage-divided to be attenuated by R1 and R2, and output from the slider 13a.

FIG. 2 shows output levels of the volume controller VC1, assuming a step-down voltage step of 10 dB for the intermediate taps 11a to 11d. For example, in case the terminals 12b and 12e of the select switch 12 are interconnected and the intermediate tap 11b is selected, the audio signal is stepped down by −10 dB by the step-down transformer 11, and the stepped down signal is further attenuated by the variable resistor 13. The attenuance at the variable resistor 13 is continuously variable.

According to the volume controller VC1, within a ½ attenuation range, a signal attenuated by the step-down transformer 11 is output to the variable resistor 13, thereby allowing the variable resistor 13 to be used in a range small of attenuation. Under this, R1 of the variable resistor 13 is relatively small, and the parallel combined resistance of resistance R1 and resistance R2 is small, allowing audio quality degradation to be avoided. Further, the step-down transformer 11 has a lowered output impedance, thus allowing the resistance value of the variable resistor itself to be lowered, as well, allowing for a maintained higher audio quality.

The attenuation amount is continuously variable by the variable resistor 13, without needing the provision of a multiplicity of intermediate taps unlike the volume controller VC21, thus allowing for an economical configuration.

Description of intermediate taps of FIG. 2 has been based on a 10 dB step, while ideally, the intermediate taps should have a step of 6 dB or less. However, practically, a provision of 20 dB steps up to a −60 dB may be sufficient, where the number of intermediate taps can be four to do with.

### Second Embodiment

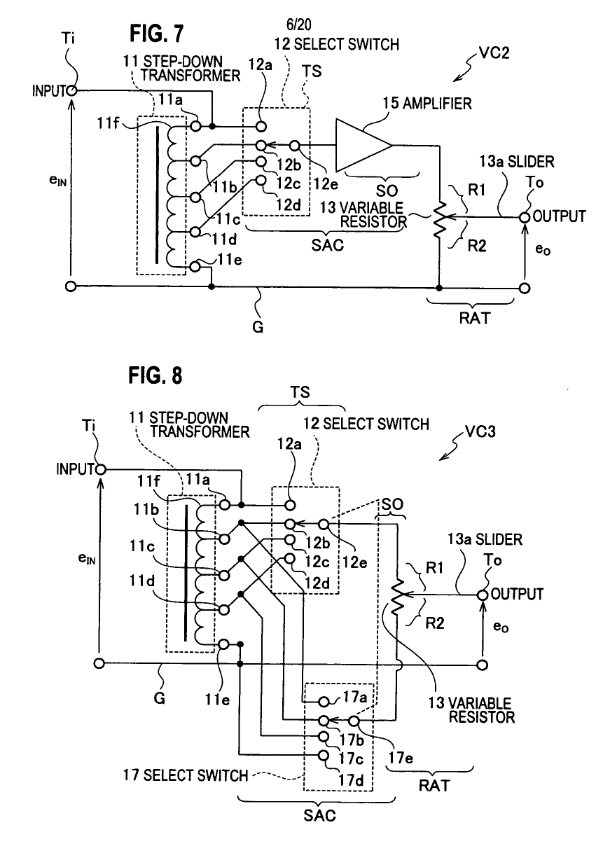

Next, description is made of a volume controller VC2 according to a second embodiment of the present invention, with reference to FIG. 7. FIG. 7 is a circuit diagram of the volume controller VC2.

The volume controller VC2 is configured with: a step-down transformer 11 configured for a voltage step-down to attenuate an audio signal input from an unshown signal source; a signal acquirer SAC configured to select one of a plurality of (five in this embodiment) intermediate taps 11a, 11b, 11c, 11d, and 11e different of attenuance of the transformer 11 to thereby acquire a corresponding audio signal; and a resistance attenuator RAT configured to attenuate an audio signal input from the signal acquirer SAC.

The step-down transformer 11 has a winding 11f to have the audio signal input from the signal source, and the intermediate taps 11a to 11e are provided on the winding 11f.

The signal acquirer SAC is configured with: a select switch 12 as an intermediate tap selector TS for performing an intermediate tap selection by switching the intermediate taps 11a to 11d; and an amplifier 15 as a signal outputter SO for amplifying an output of the select switch 12 to output an audio signal to be input to the resistance attenuator RAT.

The resistance attenuator RAT is configured with a variable resistor 13 connected to the signal acquirer SAC.

Namely, the volume controller VC2 includes, in addition to configuration of the volume controller VC1, the amplifier 15 connected to an output side of the select switch 12 selecting an intermediate tap 11a to 11d of the step-down transformer 11, the amplifier 15 being connected at its output side to the variable resistor 13. The amplifier 15 has an input impedance sufficiently high (10 or more times) than an output impedance of the step-down transformer 11 not to influence outputs of the step-down transformer 11, and has a sufficient output capacity (current, voltage) to drive the variable resistor 13, and an output impedance low enough (one tenth or less) relative to the variable resistor 13.

The volume controller VC2 has a decreased signal current inflowing from an intermediate tap 11a to 11d to the amplifier 15, allowing for a still improved audio quality in comparison with the volume controller VC1. Further, since a variable resistor low of resistance value is employable as the variable resistor 13, the impedance at output end can be low, constituting together with stray capacitances a high frequency attenuating filter having a still higher cut-off frequency, with expectable improvements in characteristics and audio quality.

### Third Embodiment

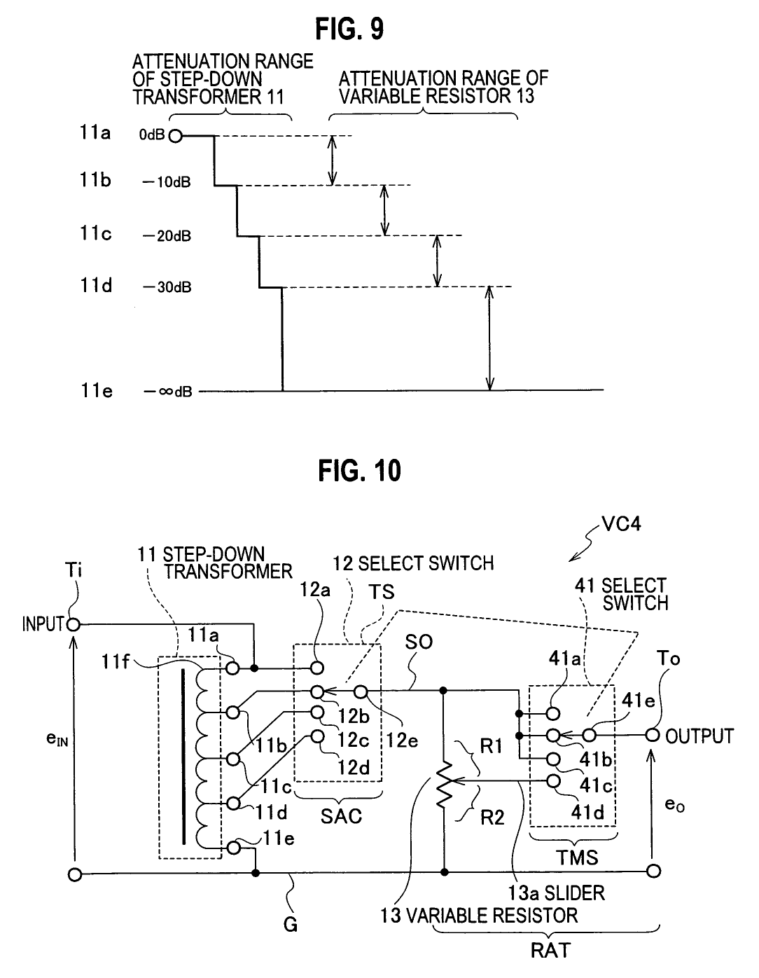

Next, description is made of a volume controller VC3 according to a third embodiment of the present invention, with reference to FIG. 8 and FIG. 9. FIG. 8 is a circuit diagram of the volume controller VC3, and FIG. 9, an output level diagram of the volume controller VC3.

The volume controller VC3 is configured with: a step-down transformer 11 configured for a voltage step-down to attenuate an audio signal input from an unshown signal source; a signal acquirer SAC configured to select one of a plurality of (five in this embodiment) intermediate taps 11a, 11b, 11c, 11d, and 11e different of attenuance of the transformer 11 to thereby acquire a corresponding audio signal; and a resistance attenuator RAT configured to attenuate an audio signal input from the signal acquirer SAC.

The step-down transformer 11 has a winding 11f to have the audio signal input from the signal source, and the intermediate taps 11a to 11e are provided on the winding 11f.

The signal acquirer SAC is configured with: an intermediate tap selector TS for performing an intermediate tap selection by switching the intermediate taps 11a to 11d; and a signal outputter SO for outputting an audio signal to be input to the resistance attenuator RAT from the intermediate tap selector TS.

The intermediate tap selector TS has a plurality of (two in this embodiment) select switches for selecting different intermediate taps among the intermediate taps 11a to 11e, that is, mutually interlocked select switches 12 and 17, and the signal outputter SO inputs to the resistance attenuator RAT an audio signal made of a difference between audio signals acquired by the select switches 12 and 17.

The resistance attenuator RAT is configured with a variable resistor 13 connected to the signal acquirer SAC.

Namely, as shown in FIG. 8, the volume controller VC3 is configured with: the step-down transformer 11 having the plurality of intermediate taps 11a to 11e for attenuating an input audio signal; the select switch 12 having switch terminals 12a to 12d for selecting one of the intermediate taps 11a to 11d; the select switch 17 having switch terminals 17a to 17d for selecting one of the intermediate taps 11b to 11e; and the variable resistor 13 connected at one input end to an output terminal 12e of the select switch 12 and at the other input end to an output terminal 17e of the select switch 17, and adapted for the audio signal to be continuously attenuated to be output.

The intermediate taps 11a to 11e have different attenuances, of which intermediate taps 11a to 11d are connected to the switch terminals 12a to 12d of the select switch 12, and intermediate taps 11b to 11e are connected to the switch terminals 17a to 17d of the select switch 17. The select switch 12 and the select switch 17 are interlocked, so that an intermediate tap selected by the select switch 17 is set lower by one step than an intermediate tap selected by the select switch 12. Further, the variable resistor 13 is provided with a slider 13a, and has a resistance between the slider 13a and the output terminal 12e, designated at R1, and a resistance of the rest designated at R2.

In the volume controller VC3, voltage of an input audio signal is stepped down by the step-down transformer 11, and stepped down audio signals are output from intermediate taps to the variable resistor 13 via the select switch 12 and the select switch 17.

For example, when the switch terminals 12b and 12e of the select switch 12 are interconnected and the switch terminals 17b and 17e of the select switch 17 are interconnected, signals are output to the variable resistor 13, from the intermediate tap 11b via the switch terminals 12b and 12e, and from the intermediate tap 11c via the switch terminals 17b and 17e.

The signal input to the variable resistor 13 is voltage-divided to be attenuated by the voltage dividing resistances R1 and R2, and output from the slider 13a.

FIG. 9 shows output levels of the variable resistor 13 in the case the intermediate taps 11a to 11e have a 10 dB step of attenuance. For example, in case the switch terminals 12b and 12e of the select switch 12 are interconnected and the switch terminals 17b and 17e of the select switch 17 are interconnected, a signal stepped down by −10 dB by the step-down transformer 11 is output to the output terminal 12e, and a signal stepped down by −20 dB by the step-down transformer 11 is output to the output terminal 17e. The variable resistor 13a is adapted for a continuous change of level difference between the output terminal 12e and the output terminal 17e.

The volume controller VC3 can use the variable resistor 13 in respective steps of attenuation range of the step-down transformer 11, allowing for the use within a range small of attenuation of the variable resistor 13. Since R1 of the variable resistor 13 is relatively small, the parallel combined resistance of resistance R1 and resistance R2 also is small, allowing audio quality degradation to be avoided. Further, for possible use under a state where the step-down transformer has a small output impedance, the resistance of variable resistor 13 can also be smaller to be used, allowing the audio quality degradation to be the more prevented.

### Fourth Embodiment

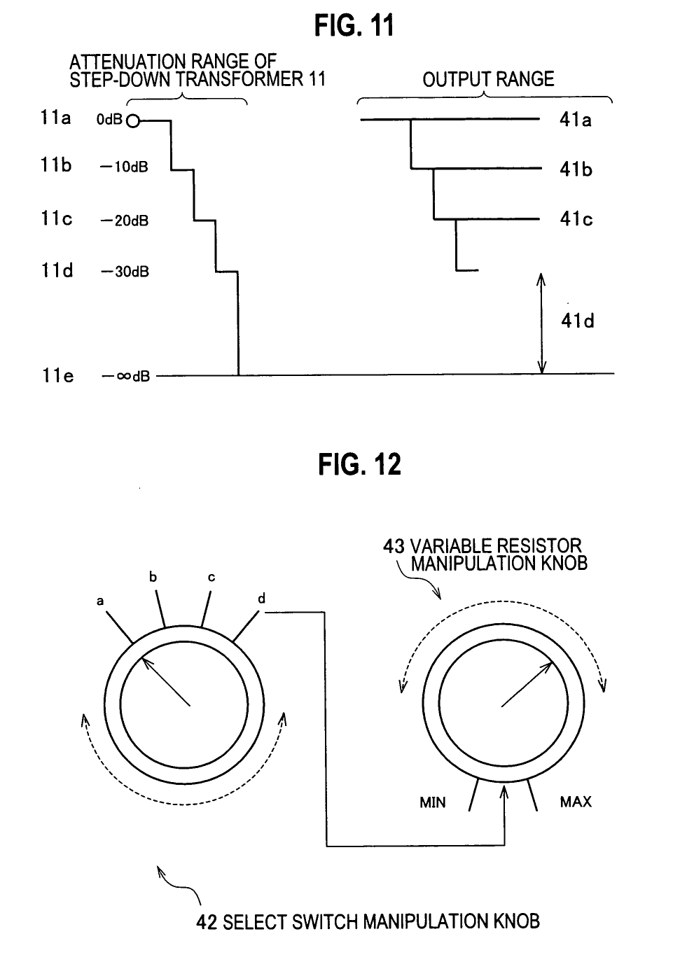

Next, description is made of a volume controller VC4 according to a fourth embodiment of the present invention, with reference to FIG. 10 to FIG. 12. FIG. 10 is a circuit diagram of the volume controller VC4, FIG. 11, an output level diagram of the volume controller VC4, and FIG. 12, a user interface of the volume controller VC4.

The volume controller VC4 is configured with: a step-down transformer 11 configured for a voltage step-down to attenuate an audio signal input from an unshown signal source; a signal acquirer SAC configured to select one of a plurality of (five in this embodiment) intermediate taps 11a, 11b, 11c, 11d, and 11e different of attenuance of the transformer 11 to thereby acquire a corresponding audio signal; and a resistance attenuator RAT configured to attenuate an audio signal input from the signal acquirer SAC.

The step-down transformer 11 has a winding 11f to have the audio signal input from the signal source, and the intermediate taps 11a to 11e are provided on the winding 11f.

The signal acquirer SAC is configured with: an intermediate tap selector TS for performing an intermediate tap selection by switching the intermediate taps 11a to 11d; and a signal outputter SO for outputting an audio signal to be input to the resistance attenuator RAT from the intermediate tap selector TS.

The intermediate tap selector TS is configured with a select switch 12 for selecting one of the intermediate taps 11a to 11d.

The resistance attenuator RAT is configured with: a continuous variable resistor 13 connected to the signal outputter SO; a plurality of terminals 41a, 1b, and 41dc connected to the signal outputter SO; and a select switch 41 as a terminal selector TMS configured to be interlocked with the intermediate tap selection of the intermediate tap selector TS, for a terminal selection among an output terminal 41d of the continuous variable resistor 13 and the plurality of terminals 41a to 41c.

Namely, as shown in FIG. 10, the volume controller VC4 is configured by connecting the select switch 41 to configuration of the volume controller VC1. The terminals 41a to 41c of the select switch 41 are connected to the output terminal 12e of the select switch 12, and the output terminal 41d is connected to the slider 13a. Then, the select switch 41 is interlocked with the select switch 12, so that terminals 41a and 41e are interconnected when terminals 12a and 12e are interconnected, terminals 41b and 41e are interconnected when terminals 12b and 12e are interconnected, terminals 41c and 41e are interconnected when terminals 12c and 12e are interconnected, and terminals 41d and 41e are interconnected when terminals 12d and 12e are interconnected.

Thus, when the output terminal 41e and a switch terminal 41a to 41c of the select switch 41a is interconnected, a signal is output directly from an intermediate tap 11a to 11c of the step-down transformer 11.

When the terminals 41d and 41e of the select switch 41 are interconnected, a signal is output from the variable resistor 13 and can be continuously attenuated up to −∞dB.

FIG. 11 shows an output level diagram of the volume controller VC4 in the case the attenuance of the intermediate taps 11a to 11d is changed by a 10 dB step.

In selection of a terminal 41a to 41c of the select switch 41, a signal is output directly from an intermediate tap 11a to 11c of the step-down transformer 11, so that the attenuance is gradually (stepwise) changed, whereas when the switch terminal 41d of the select switch 41 is selected, a signal is output from the variable resistor 13, allowing for a continuous attenuation.

The select switches 12 and 41 and the variable resistor 13 are manipulative by use of a user interface shown in FIG. 12. For example, the terminal 12a and the terminal 41a are selective by setting a select switch manipulation knob 41 to a position “a”. The select switch manipulation knob 42 will be set to a position “d” for selection of the terminal 12d and the terminal 41d, only when a variable resistor manipulation knob 43 can be used for volume control.

When the output terminal 41e and a switch terminal 41a to 41c of the select switch 41 are interconnected, the volume controller VC4 is adapted to output a signal directly from an intermediate tap 11a to 11c of the step-down transformer 11, thus being enabled to avoid an audio quality degradation due to a detour of the signal via the variable resistor 13.

### Fifth Embodiment

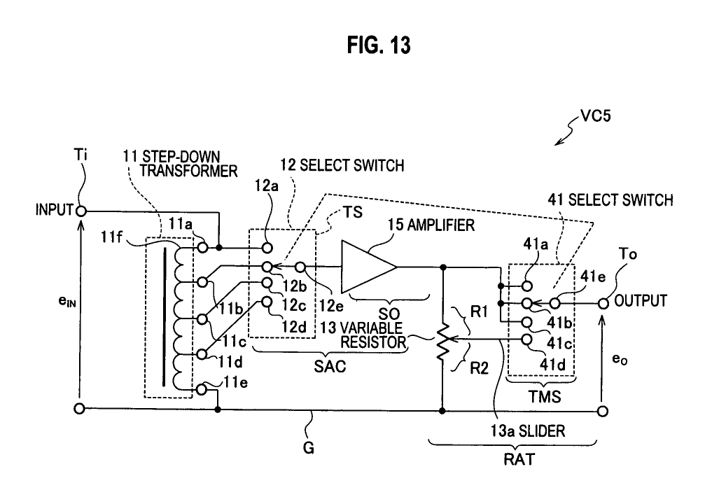

Next, description is made of a volume controller VC5 according to a fifth embodiment of the present invention, with reference to FIG. 13. FIG. 13 is a circuit diagram of the volume controller VC5.

The volume controller VC5 is configured with: a step-down transformer 11 configured for a voltage step-down to attenuate an audio signal input from an unshown signal source; a signal acquirer SAC configured to select one of a plurality of (five in this embodiment) intermediate taps 11a, 11b, 11c, 11d, and 11e different of attenuance of the transformer 11 to thereby acquire a corresponding audio signal; and a resistance attenuator RAT configured to attenuate an audio signal input from the signal acquirer SAC.

The step-down transformer 11 has a winding 11f to have the audio signal input from the signal source, and the intermediate taps 11a to 11e are provided on the winding 11f.

The signal acquirer SAC is configured with: an intermediate tap selector TS for performing an intermediate tap selection by switching the intermediate taps 11a to 11d; and a signal outputter SO for outputting an audio signal to be input to the resistance attenuator RAT from the intermediate tap selector TS.

The intermediate tap selector TS is configured with a select switch 12 for selecting one of the intermediate taps 11a to 11d, and the signal outputter SO is configured with an amplifier 15.

The resistance attenuator RAT is configured with: a continuous variable resistor 13 connected to the signal outputter SO; a plurality of terminals 41a, 41b, and 41c connected to the signal outputter SO; and a select switch 41 as a terminal selector TMS configured to be interlocked with the intermediate tap selection of the intermediate tap selector TS, for a terminal selection among an output terminal 41d of the continuous variable resistor 13 and the plurality of terminals 41a to 41c.

Namely, as shown in FIG. 13, the volume controller VC5 includes, in addition to configuration of the volume controller VC4, the amplifier 15 connected to an output side of the select switch 12 selecting an intermediate tap 11a to 11d of the step-down transformer 11, the amplifier 15 being connected at an output side thereof in parallel to the variable resistor 13 and the select switch 41. The amplifier 15 has an input impedance sufficiently high (10 or more times) than an output impedance of the step-down transformer 11 not to influence outputs of the step-down transformer 11, and has a sufficient output capacity (current, voltage) to drive the variable resistor 13, and an output impedance low enough (one tenth or less) relative to the variable resistor 13.

The volume controller VC5 has a decreased signal current inflowing from an intermediate tap 11a to 11d to the amplifier 15, allowing for a still improved audio quality in comparison with the volume controller VC4. Further, the variable resistor 13 can have a resistance thereof set low, allowing for improved characteristics and audio quality.

### Sixth Embodiment

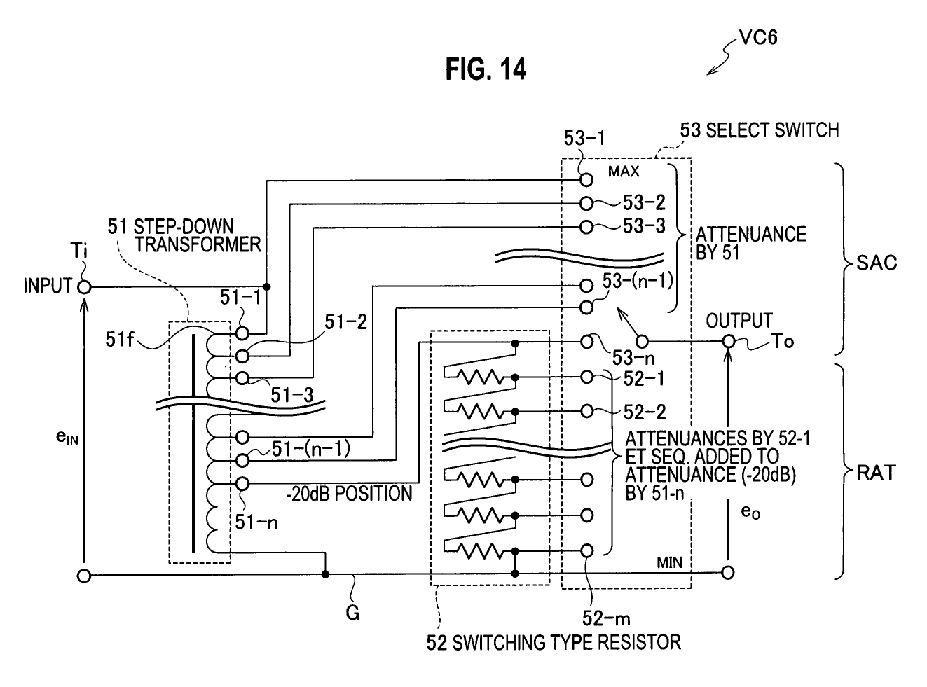

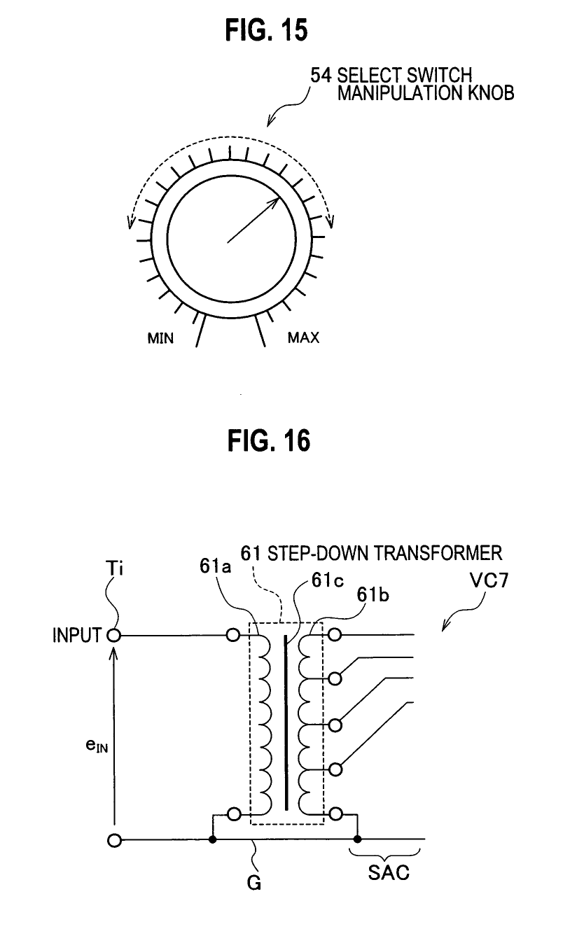

Next, description is made of a volume controller VC6 according to a sixth embodiment of the present invention, with reference to FIG. 14 and FIG. 15. FIG. 14 is a circuit diagram of the volume controller VC6, and FIG. 15, a user interface of the volume controller VC6.

The volume controller VC6 is configured with: a step-down transformer 51 configured for a voltage step-down to attenuate an audio signal input from an unshown signal source; a signal acquirer SAC configured to select one of n intermediate taps 51-1, 51-2, 51-3, . . . , 51-(n−1), 51-n different of attenuance of the transformer 51 to thereby acquire a corresponding audio signal; and a resistance attenuator RAT configured to attenuate an audio signal input from the signal acquirer SAC.

The step-down transformer 51 has a winding 51f to have the audio signal input from the signal source, and the intermediate taps 51-1 to 51-n are provided on the winding 51f.

The signal acquirer SAC is configured with n switch contacts 53-1, 53-2, 53-3, . . . , 53-(n−1), 53-n connected to the n intermediate taps 51-1 to 51-n.

The resistance attenuator RAT is configured with: a switching type resistor 52 having m fixed resistors connected in series to one 53-n of the n switch contacts 53-1 to 53-n; m switch contacts 52-1, 52-2, . . . , 52-m connected to nodes between the m fixed resistors; and a select switch 53 having a selector adapted for selection among the n switch contacts 53-1 to 53-n and the m switch contacts 52-1 to 52-m.

That one 53-n of the switch contacts to which the m serial fixed resistors are connected is connected to an intermediate tap 51-n that has a greatest attenuance in the n intermediate taps 51-1 to 51-n.

Namely, the volume controller VC6 is configured with: the step-down transformer 51 having n intermediate taps 51-1 to 51-n for attenuating an input audio signal; the switching type resistor 52 provided with the m fixed resistors connected in series to each other, having the m switch terminals 52-1 to 52-m in which an audio signal input from the intermediate tap 51-n greatest of attenuance is stepwise attenuated to be output; and the select switch 53 having a selector adapted to select one of the m switch terminals 52-1 to 52-m and the n switch contacts 53-1 to 53-n connected to the intermediate taps 51-1 to 51-n.

The volume controller VC6 is adapted for a voltage step-down of an input audio signal by the step-down transformer 51. The stepped down audio signal is output via a terminal 53-1 to 53-n of the select switch 53 connected to an intermediate tap 51-1 to 51-n.

To obtain attenuances exceeding the attenuance (e.g. −20 dB) of the intermediate tap 51-n, the audio signal is additionally attenuated in the switching type resistor 52, to be output via a switch terminal 52-1 to 52-m doubling as an output terminal of the switching type resistor 52 in the select switch 53.

The volume controller VC6 simply has a select switch manipulation knob 54 shown in FIG. 15 as a user interface, with a more improved conveniency of manipulation than the user interface shown in FIG. 12.

### Seventh Embodiment

Next, description is made of a volume controller VC7 according to a seventh embodiment of the present invention, with reference to FIG. 16. FIG. 16 is a circuit diagram of an essential portion of the volume controller VC7.

The volume controller VC7 is different from the first to the sixth embodiment VC1 to VC6 in employment of a step-down transformer 61 having a primary and secondary independent winding structure, as shown in FIG. 16. The transformer 61 has wound, on a core 61c, a primary winding 61a to which an audio signal is input from an input terminal Ti, and a secondary winding 61b on which intermediate taps are provided for connection with a signal acquirer SAC, whereby interferences are decreased, allowing for a still improved audio quality.

The transformer 61 may be a step-up transformer. In particular, providing a sufficient output current capacity of an amplifier installed in a front stage of the volume controller VC7, a step-up transformer low of input impedance can be employed to thereby have a yet improved audio quality.

The material of the core 61c may be a permalloy or senalloy for the transformer 61 to have a raised performance. The structure of the transformer 61 may ideally be a toroidal type, although it may be a cut-core type that can afford a good performance.

In the first to the sixth embodiment, as well, a step-down transformer 61 having a primary and secondary independent winding structure may be employed in place of the step-down transformer described.

### Eighth Embodiment

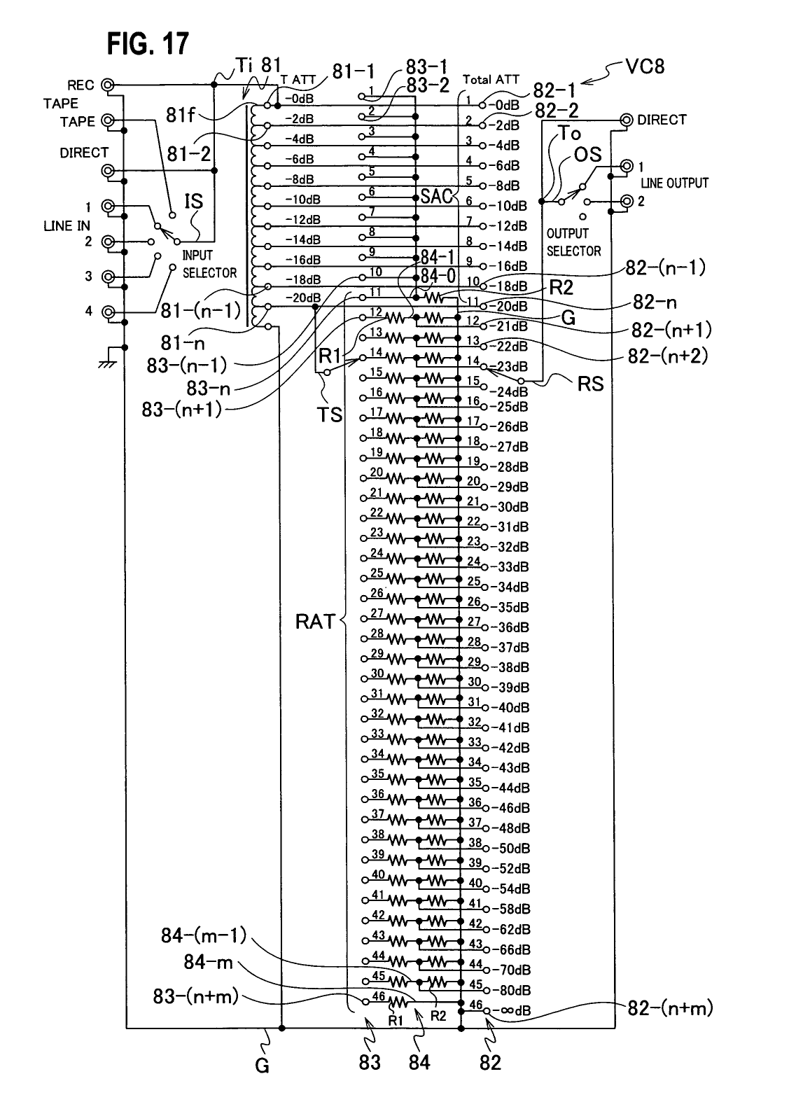

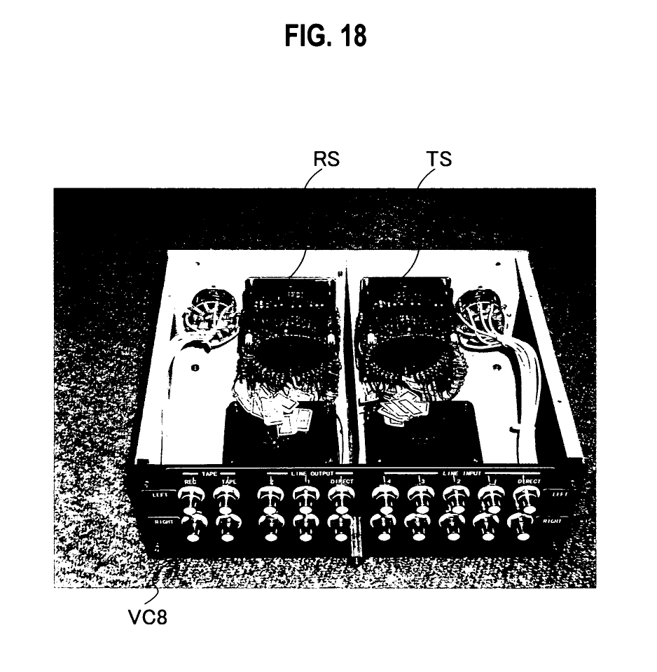

Next, description is made of a volume controller VC8 according to an eighth embodiment of the present invention, with reference to FIG. 17 and FIG. 18. FIG. 17 is a circuit diagram of the volume controller VC8, and FIG. 18, a photograph of the volume controller VC8.

The volume controller VC8 is configured with: a step-down transformer 81 configured for a voltage step-down to attenuate an audio signal input from a plurality of signal sources (e.g. REC, TAPE, LINE IN 1 to 4) via a direct input terminal DIRECT or an input selector IS and an input terminal Ti; a signal acquirer SAC provided with n (n=11, in this embodiment) switch contacts 82-1, 82-2, . . . , 82-(n−1), 82-n connected to n intermediate taps 81-1, 81-2, . . . , 81-(n−1), 81-n different of attenuance of the transformer 81, and configured for selecting one of them to thereby acquire a corresponding audio signal; and a resistance attenuator RAT configured to attenuate an audio signal input from the signal acquirer SAC.

The resistance attenuator RAT is configured with: an input side switch contact selector TS connected to the switch contact 82-n largest of attenuance (−20 dB) in the n switch contacts 82-1 to 82-n; m+1 (m+1=35+1=36, in this embodiment) switch contacts 83-n, 83-(n+1), . . . , 83-(n+m), excluding the first n−1 switch contacts as dummies, of n+m (n+m=11+35=46, in this embodiment) switch contacts 83-1, 83-2, . . . , 83-(n+m) selective by the selector TS; and m+1 resistance circuits 84-0, 84-1, . . . , 84-(m−1), 84-m respectively connected between the m+1 switch contacts 83-n, . . . , 83-(n+m) and a ground line G. Among the m+1 resistance circuits, the first resistance circuit 84-0 is configured with a fixed resistance R2, the succeeding m−1 resistance circuits 84-1 to 84-(m−1) are configured as fixed voltage dividing circuits using fixed resistances R1 and R2, and the final resistance circuit 84-m is configured with a fixed resistance R1.

The resistance attenuator RAT further includes: a total number of m switch contacts 82-(n+1), 82-(n+2), . . . , 82-(n+m) connected to divided-voltage output ends of the m-1 resistance circuits 84-1 to 84-(m−1) configured as fixed voltage dividing circuits and a grounded end of the final resistance circuit 84-m of the m+1 resistance circuits; and an output side switch contact selector RS adapted for selection of the m switch contacts 82-(n+1) to 82-(n+m) and the n switch contacts 82-1 to 82-n of the signal acquirer SAC, that is, adapted for selection of a total number of n+m switch contacts 82-1 to 82-(n+m), the selector RS being connected to an output terminal To.

Namely, the volume controller VC8 is configured with: the step-down transformer 81 having the n intermediate taps 81-1 to 81-n for stepwise attenuation within an attenuation range of −0 d to −20 dB; a select switch 82 having the n+m switch contacts 82-1 to 82-(n+m) annularly arranged as shown in FIG. 18, and the selector RS therefor; and a select switch 83 having the n+m switch contacts 83-1 to 83-(n+m) likewise annularly arranged, and the selector TS therefor; as well as with an attenuating resistor group 84 having arranged in parallel the m−1 fixed voltage dividing circuits 84-1 to 84-(m−1) adapted for stepwise attenuation within an attenuation range of −21 dB to −80 dB by a concurrent serial usage of the intermediate tap 81-n largest (−20 dB) of attenuation of the step-down transformer 81, and a fixed voltage dividing circuit 84-m of R11≢ vs. 0Ω corresponding to an attenuation of −∞dB.

Thus, the output terminal To receives an audio signal appropriately attenuated by the transformer 81 and/or the resistor group 84, which audio signal is output from the output terminal To, via a direct output terminal DIRECT or an output selector OS, to (an) output line connection terminal(s) LINE OUTPUT-1 and/or LINE OUTPUT-2.

The step-down transformer 81 of the eighth embodiment VC8 has a winding 81f, of which specifications are listed in the Table below. This Table is applicable also to step-down transformers of other embodiments.

Step-Down Transformer Winding Specifications

ATT (dB)

| | | |
|---|---|---|
| 0 | 1800 | End of winding |
| −2 | 1420 | |
| −4 | 1134 | |
| −6 | 900 | |
| −8 | 716 | |
| −10 | 569 | |
| −12 | 450 | |
| −14 | 359 | |
| −16 | 285 | |
| −18 | 226 | |
| −20 | 180 | |
| −∞ | 0 | Start of winding |

Like the first to the sixth embodiment VC1 to VC6, the step-down transformer 81 also is configured with intermediate taps 81-1 to 81-n provided on a winding to which an audio signal is input from an input selector IS, while, in accordance with the seventh embodiment VC7, intermediate taps may be provided on a secondary winding of a transformer having a primary winding for an audio signal to be input thereto from a signal source.

### Ninth Embodiment

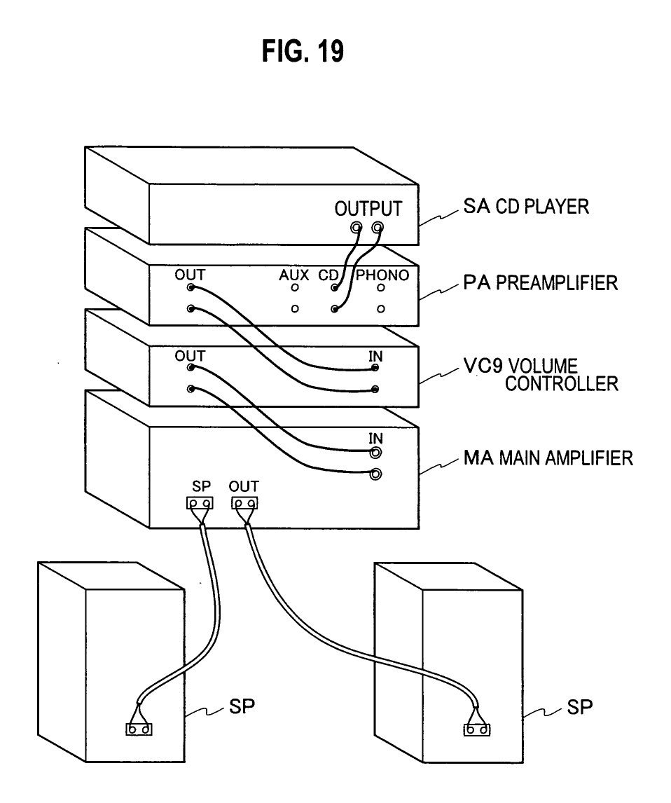

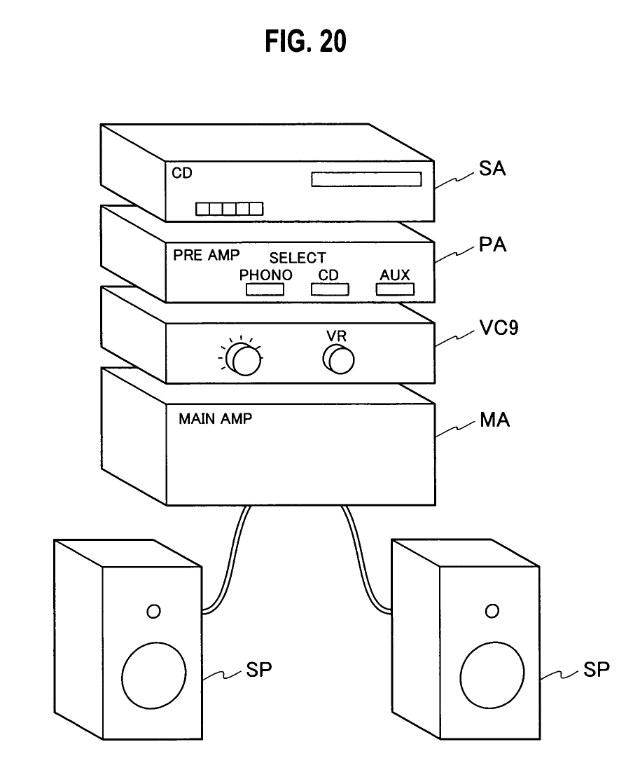

Next, description is made of an audio system including a volume controller VC9 according to a ninth embodiment of the present invention, with reference to FIG. 19 and FIG. 20. FIG. 19 is a perspective view from rear side of the audio system, and FIG. 20, a perspective view from front side of the same system.

The volume controller VC9, which may be any one of the volume controllers VC1 to VC8, is fabricated as a single unit in a prescribed size.

The audio system is configured by wiring the volume controller VC9, as illustrated, for connections with a CD player SA, a preamplifier PA, a main amplifier MA, and a pair of speakers SP, which are respectively unitized in a size corresponding to the volume controller VC9.

It is noted that each volume controller VC-1 to VC-8 according to the first to the eighth embodiment may be unitized together with a preamplifier or a main amplifier, or configured as an amplifying unit including appropriate relevant equipment. This can realize a good level balance with reduced wirings, as well as decreased stray capacitances, allowing for minimized audio quality degradation. Specific examples are shown below.

### Tenth Embodiment

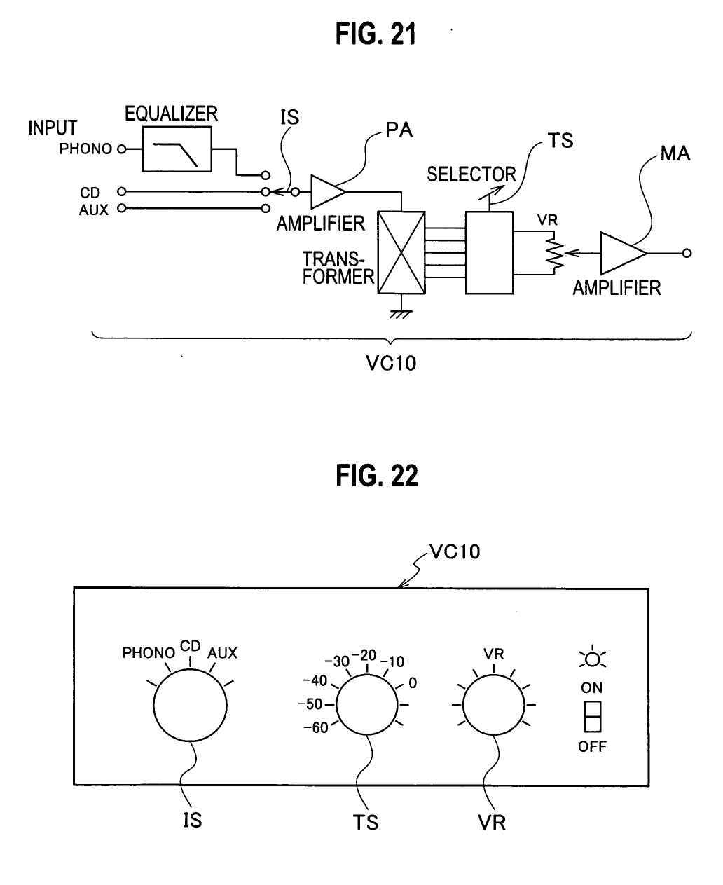

Description is made of a volume controller VC10 according to a tenth embodiment of the present invention, with reference to FIG. 21 and FIG. 22. FIG. 21 is a block diagram of the volume controller VC10, and FIG. 22, a front view of the volume controller VC10.

The volume controller VC10 is configured as a unit including an equalizer, an input selector IS, a preamplifier PA, and a main amplifier MA. VR is a volume control knob.

### Eleventh Embodiment

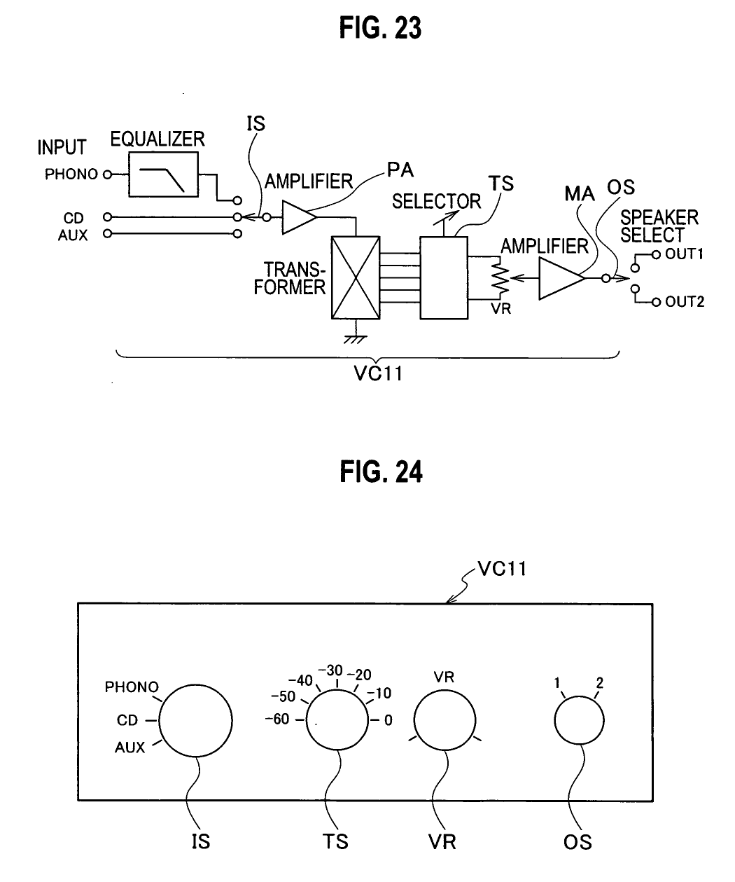

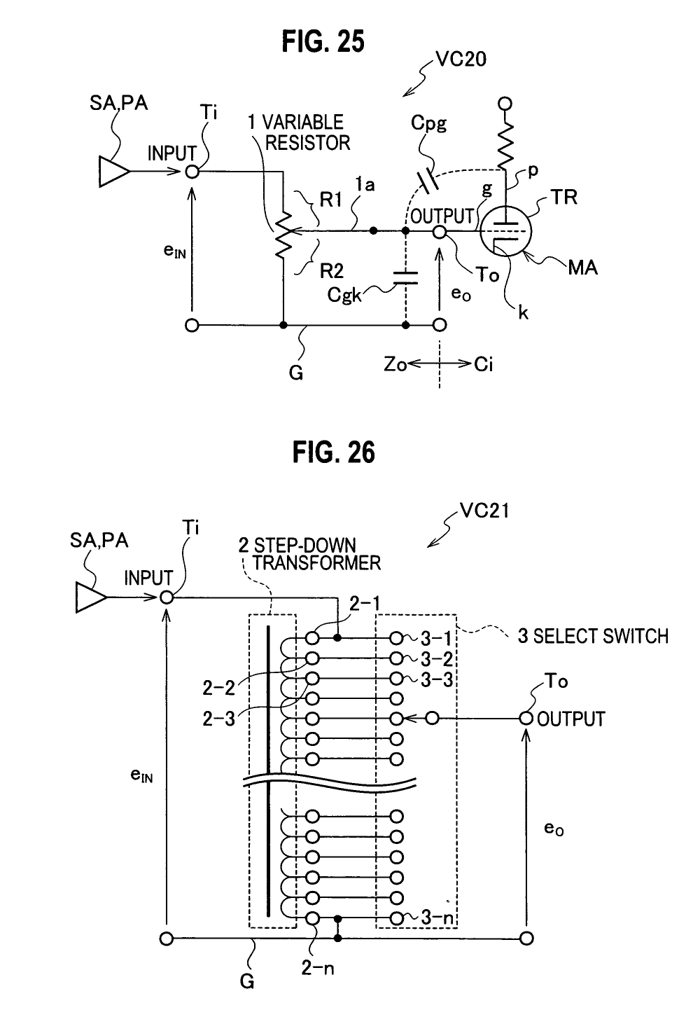

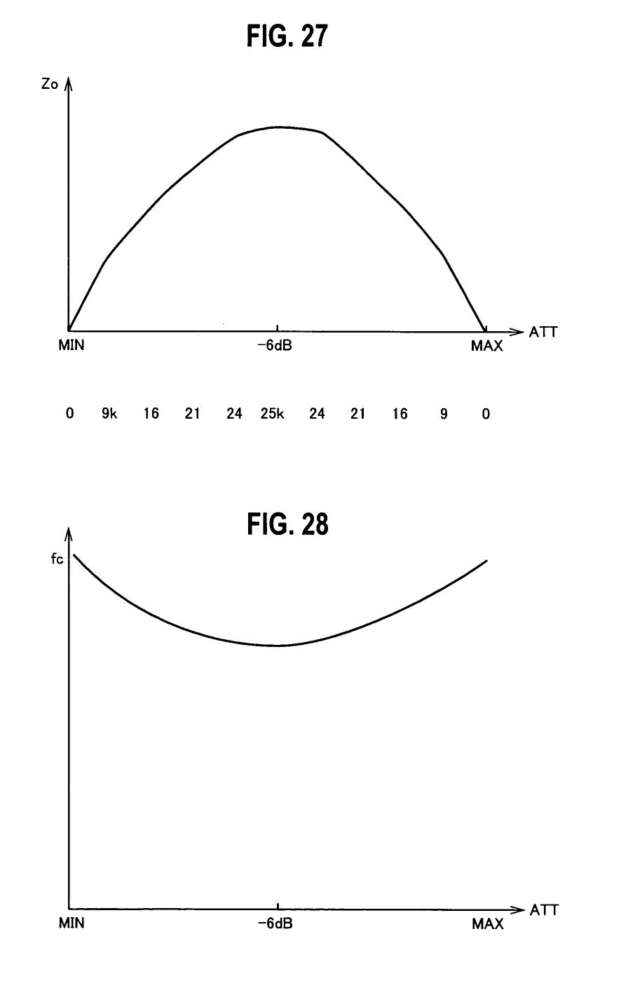

Description is made of a volume controller VC11 according to an eleventh embodiment of the present invention, with reference to FIG. 23 and FIG. 24. FIG. 23 is a block diagram of the volume controller VC11, and FIG. 24, a front view of the volume controller VC11.

The volume controller VC11 additionally includes an output selector OS, in comparison with the volume controller VC10.

### Other Description

As will be apparent from the foregoing description, according to each embodiment of the present invention, an audio signal input from a signal source to a transformer and high-attenuated is acquired by a signal acquirer, and an audio signal input from the signal acquirer is attenuated by a resistance attenuator, whereby the resistance attenuator can do without using a ½ attenuation range, allowing for a suppressed audio quality degradation about the ½ attenuation range even with a simplified configuration.

Further, due to the provision of a step-down transformer for voltage step-down of an input audio signal and a variable resistor for continuous attenuation of a signal stepped down by the step-down transformer, if in a high attenuation range a signal high-attenuated by the step-down transformer is output to a variable resistor type attenuator, the variable resistor can do without using a ½ attenuation range, allowing for a suppressed audio quality degradation about the ½ attenuation range even with a simplified configuration.

It will be understood that the foregoing description of embodiments are not restrictive, but ever illustrative, and artisan could make various modifications within the scope of the appended claims.

For example, letting Ra be a resistance at the higher potential side than a sliding contact of a resistance type voltage divider, and Rb be a resistance at the lower potential side, the voltage gain (attenuance) is given by Rb/(Ra+Rb), and the output impedance, by Ra×Rb/(Ra+Rb), wherefor the volume controller VC6 according to the sixth embodiment and the volume controller VC8 according to the eighth embodiment can employ the following configurations with respect to their resistance attenuators RAT.

For the switching type resistor 52 of the volume controller VC6, letting Ri be a resistance value of an i-th (1≦i≦m) fixed resistance connected to an i-th switch terminal 52-i, the resistance value may be set so that Ri gets smaller as i approaches m. A facilitated equalization can thereby be achieved of attenuation step widths of a serial resistor group.

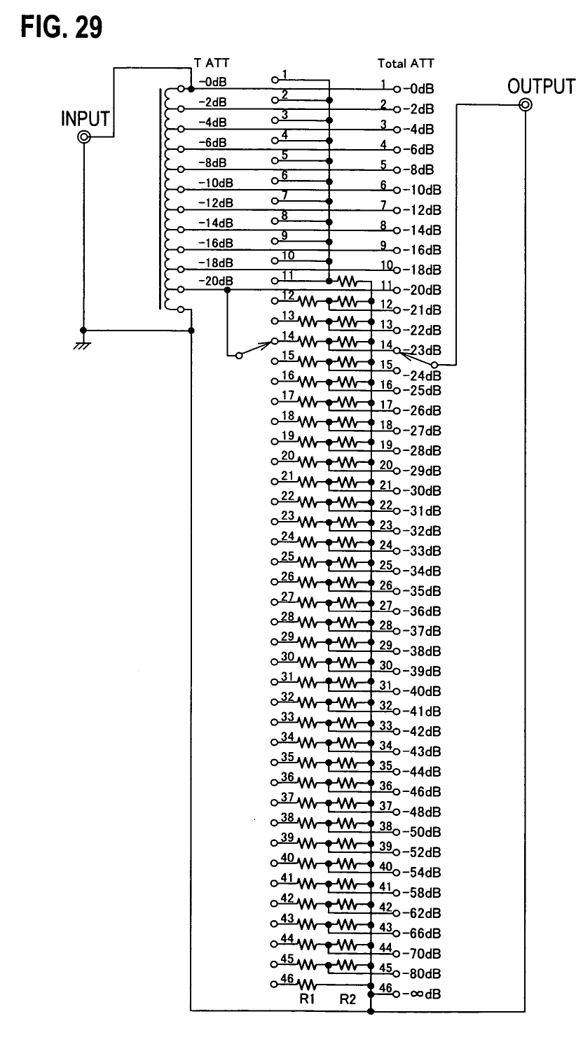

Further, for the attenuating resistor group 84 of the volume controller VC8, assuming the sum of resistances R1 and R2 of fixed voltage dividing circuit 84-i (1≦i≦m) to be kept substantially constant irrespective of i, the resistance values may be set so that R1 gets larger (hence R2 gets smaller) as i approaches m. Specifically, a volume controlling circuit (FIG. 29) of the volume controller VC8 may be given specifications shown in the Table on the next page.

By this, a facilitated equalization can be achieved of attenuation step widths of a parallel resistor group, besides the use of a system switching parallel resistances, in which signals are free from detouring many fixed resistors, with a reduced audio quality degradation, allowing for the higher audio quality.

The present application claims the benefits of priority based on Japanese Patent Application No. 2005-084807, filed on Mar. 23, 2005, in the Japanese Patent Office, of which contents are incorporated herein by reference.

Specifications for Volume Controlling Circuit

| | De- | Indi- | | | | Actual | Attenu- |
|---|---|---|---|---|---|---|---|
| Contact | signed | ca- | RATT | R1 | R2 | measured | ation |
| No. | gain | tion | gain | (Ω) | (Ω) | gain | step |
| 1 | 0 | 0 | 0 | 0 | 1000 | | |
| 2 | −2 | | 0 | 0 | ↑ | | |
| 3 | −4 | −4 | 0 | 0 | ↑ | | |
| 4 | −6 | | 0 | 0 | ↑ | | |
| 5 | −8 | −8 | 0 | 0 | ↑ | | |
| 6 | −10 | | 0 | 0 | ↑ | | |
| 7 | −12 | −12 | 0 | 0 | ↑ | | |
| 8 | −14 | | 0 | 0 | ↑ | | |
| 9 | −16 | −16 | 0 | 0 | ↑ | | |
| 10 | −18 | | 0 | 0 | ↑ | | |
| 11 | −20 | −20 | 0 | 0 | ↑ | | |
| 12 | −21 | | −1 | 110 | 887 | | |
| 13 | −22 | −22 | −2 | 205 | 787 | | |
| 14 | −23 | | −3 | 294 | 715 | | |
| 15 | −24 | −24 | −4 | 365 | 634 | | |
| 16 | −25 | | −5 | 442 | 562 | | |
| 17 | −26 | −26 | −6 | 499 | 499 | | |
| 18 | −27 | | −7 | 549 | 442 | | |
| 19 | −28 | −28 | −8 | 604 | 402 | | |
| 20 | −29 | | −9 | 649 | 357 | | |
| 21 | −30 | −30 | −10 | 681 | 316 | | |
| 22 | −31 | | −11 | 715 | 280 | | |
| 23 | −32 | −32 | −12 | 750 | 249 | | |
| 24 | −33 | | −13 | 768 | 226 | | |
| 25 | −34 | −34 | −14 | 806 | 200 | | |
| 26 | −35 | | −15 | 825 | 178 | | |
| 27 | −36 | −36 | −16 | 845 | 158 | | |
| 28 | −37 | | −17 | 866 | 140 | | |
| 29 | −38 | −38 | −18 | 866 | 127 | | |
| 30 | −39 | | −19 | 887 | 113 | | |
| 31 | −40 | −40 | −20 | 909 | 100 | | |
| 32 | −41 | | −21 | 909 | 88.7 | | |
| 33 | −42 | −42 | −22 | 931 | 78.7 | | |
| 34 | −43 | | −23 | 931 | 71.5 | | |
| 35 | −44 | −44 | −24 | 931 | 63.4 | | |
| 36 | −46 | | −26 | 953 | 49.9 | | |
| 37 | −48 | −48 | −28 | 953 | 40.2 | | |
| 38 | −50 | | −30 | 976 | 31.6 | | |
| 39 | −52 | −52 | −32 | 976 | 24.9 | | |
| 40 | −54 | | −34 | 976 | 20 | | |
| 41 | −58 | −58 | −38 | 976 | 12.7 | | |
| 42 | −62 | | −42 | 1000 | 7.87 | | |
| 43 | −66 | −66 | −46 | 1000 | 4.99 | | |
| 44 | −70 | | −50 | 1000 | 3.16 | | |
| 45 | −80 | −80 | −60 | 1000 | 1 | | |
| 46 | −∞ | | −∞ | 1000 | 0 | | |
| | | | | | | dB | dB |

What is claimed is:

1. A volume controller comprising:
a transformer having an audio signal input from a signal source;
a signal acquirer configured to select an intermediate tap of the transformer, to thereby acquire an audio signal corresponding thereto; and
a resistance attenuator configured to attenuate an audio signal input from the signal acquirer.

2. The volume controller as claimed in claim 1, wherein the transformer comprises a step-down transformer configured to attenuate the audio signal input from the signal source, the step-down transformer having a plurality of intermediate taps different of attenuance, and the signal acquirer performs a selection of the intermediate tap among the plurality of intermediate taps.

3. The volume controller as claimed in claim 1, wherein the transformer has a winding to have the audio signal input from the signal source, the winding being provided with the intermediate tap.

4. The volume controller as claimed in claim 1, wherein the transformer has a primary winding to have the audio signal input from the signal source, and a secondary winding provided with the intermediate tap.

5. The volume controller as claimed in claim 2, wherein the signal acquirer comprises an intermediate tap selector configured to perform the selection of the intermediate tap by switching the plurality of intermediate taps, and a signal outputter configured to output an audio signal to be input to the resistance attenuator.

6. The volume controller as claimed in claim 5, wherein the intermediate tap selector has a plurality of select switches configured to select different intermediate taps among the plurality of intermediate taps, and the signal outputter is configured to input to the resistance attenuator an audio signal made of a difference between audio signals acquired by the plurality of select switches.

7. The volume controller as claimed in claim 5, wherein the signal outputter comprises an amplifier configured to amplify a signal to be input to the resistance attenuator.

8. The volume controller as claimed in claim 2, wherein the resistance attenuator comprises a continuous variable resistor connected to the signal acquirer.

9. The volume controller as claimed in claim 8, wherein the signal acquirer comprises a first select switch having switch contacts connected to the plurality of intermediate taps, respectively,
wherein the resistance attenuator comprises:
the continuous variable resistor connected to an output end of the first select switch; and
a second select switch having a plurality of switch contacts connected to the output end of the first select switch, and a switch contact connected to a slider of the continuous variable resistor, and
wherein the second select switch is interlocked with the first select switch.

10. The volume controller as claimed in claim 2, wherein the signal acquirer comprises a first plurality of switch contacts connected to the plurality of intermediate taps, and
wherein the resistance attenuator comprises:
a plurality of serial fixed resistors connected to one of the first plurality of switch contacts,
a second plurality of switch contacts connected to nodes between the plurality of fixed resistors, and
a select switch adapted for selection of the first plurality of switch contacts and the second plurality of switch contacts.

11. The volume controller as claimed in claim 10, wherein one of the first plurality of switch contacts connected to the plurality of serial fixed resistors is connected to an intermediate tap having a maximal attenuance among the plurality of intermediate taps.

12. The volume controller as claimed in claim 2, wherein the signal acquirer comprises a first plurality of switch contacts connected to the plurality of intermediate taps, and
wherein the resistance attenuator comprises:
a first select switch connected to one of the first plurality of switch contacts;
a second plurality of switch contacts selective by the first select switch;
a plurality of fixed voltage dividing circuits connected to the second plurality of switch contacts, respectively;
a third plurality of switch contacts connected to output ends of the plurality of fixed voltage dividing circuits; and
a second select switch adapted for selection of the first plurality of switch contacts and the third plurality of switch contacts.

13. A volume controller comprising:
a step-down transformer configured to attenuate an input audio signal, and provided with a plurality of intermediate taps to output the audio signal depending on respective attenuances;
a select switch configured to select one of the plurality of intermediate taps in accordance with a manipulation; and
a variable resistor connected to an output side of the select switch, and adapted for the audio signal to be continuously attenuated to be output by a change of resistance value in accordance with a manipulation.

14. The volume controller as claimed in claim 13, wherein the step-down transformer is a step-down transformer having a primary and secondary independent winding structure.

15. A volume controller comprising:
a step-down transformer configured to attenuate an input audio signal, and provided with a plurality of intermediate taps to output the audio signal depending on respective attenuances;
a select switch configured to select one of the plurality of intermediate taps in accordance with a manipulation;
an amplifier connected to an output side of the select switch and configured to amplify the audio signal; and
a variable resistor connected to an output side of the amplifier, and adapted for the audio signal to be continuously attenuated to be output by a change of resistance value in accordance with a manipulation.

16. The volume controller as claimed in claim 15, wherein the step-down transformer is a step-down transformer having a primary and secondary independent winding structure.

17. A volume controller comprising:
a step-down transformer configured to attenuate an input audio signal, and provided with a plurality of intermediate taps to output the audio signal depending on respective attenuances;
a first select switch configured to select one of the plurality of intermediate taps in accordance with a manipulation;
a second select switch configured to select one of the plurality of intermediate taps in accordance with a manipulation; and
a variable resistor having an input end connected to an output side of the first select switch and another input end connected to an output side of the second select switch, and adapted for the audio signal to be continuously attenuated to be output by a change of resistance value in accordance with a manipulation.

18. The volume controller as claimed in claim 17, wherein the step-down transformer is a step-down transformer having a primary and secondary independent winding structure.

19. A volume controller comprising:
a step-down transformer configured to attenuate an input audio signal, and provided with a plurality of intermediate taps to output the audio signal depending on respective attenuances;
a first select switch configured to select one of the plurality of intermediate taps in accordance with a manipulation;
a variable resistor connected to an output side of the first select switch, and adapted for the audio signal to be continuously attenuated to be output by a change of resistance value in accordance with a manipulation; and
a second select switch connected to output sides of the variable resistor and the first select switch, and configured to operate in an interlocked manner with the first select switch in accordance with a manipulation,
the second select switch being adapted to output an output signal of the variable resistor simply when the first select switch selects an intermediate tap at which the audio signal has a maximized attenuance, and output an output signal of the first select switch when the first select switch selects another intermediate tap.

20. The volume controller as claimed in claim 19, wherein the step-down transformer is a step-down transformer having a primary and secondary independent winding structure.

21. A volume controller comprising:
a step-down transformer configured to attenuate an input audio signal, and provided with a plurality of intermediate taps to output the audio signal depending on respective attenuances;
a first select switch configured to select one of the plurality of intermediate taps in accordance with a manipulation;
an amplifier connected to an output side of the first select switch, and configured to amplify the audio signal;
a variable resistor connected to an output side of the amplifier, and adapted for the audio signal to be continuously attenuated to be output by a change of resistance value in accordance with a manipulation; and
a second select switch connected to output sides of the variable resistor and the first select switch, and configured to operate in an interlocked manner with the first select switch in accordance with a manipulation,
the second select switch being adapted to output an output signal of the variable resistor simply when the first select switch selects an intermediate tap at which the audio signal has a maximized attenuance, and output an output signal of the first select switch when the first select switch selects another intermediate tap.

22. The volume controller as claimed in claim 21, wherein the step-down transformer is a step-down transformer having a primary and secondary independent winding structure.

23. A volume controller comprising:
a step-down transformer configured to attenuate an input audio signal, and provided with a plurality of intermediate taps to output the audio signal depending on respective attenuances;
a switching type resistor having an input terminal connected to an intermediate tap at which the audio signal has a maximized attenuance, and a plurality of output terminals adapted for the audio signal input from the intermediate tap to be stepwise attenuated to be output; and
a select switch configured to select one of the plurality of intermediate taps and the plurality of output terminals of the switching type resistor in accordance with a manipulation.

24. The volume controller as claimed in claim 23, wherein the step-down transformer is a step-down transformer having a primary and secondary independent winding structure.
